(19) United States
(12) Patent Application Publication
(10) Pub. No.: US 2023/0231528 A1
(43) Pub. Date: Jul. 20, 2023

(54) Resonator and preparation method of a resonator, and filter

(71) Applicant: Wuhan MEMSonics Technologies Co.,Ltd., Wuhan (CN)

(72) Inventors: Tiancheng LUO, Wuhan (CN); Yao CAI, Wuhan (CN); Chao GAO, Wuhan (CN); Yang ZOU, Wuhan (CN); Binghui LIN, Wuhan (CN); Kaixiang LONG, Wuhan (CN); Bowoon SOON, Singapore (SG); Chengliang SUN, Wuhan (CN)

(21) Appl. No.: 18/097,521

(22) Filed: Jan. 17, 2023

(30) Foreign Application Priority Data
Jan. 20, 2022 (CN) 202210067464.9

(51) Int. Cl. H03H 3/02; H03H 9/17; H03H 9/56

(52) U.S. Cl. CPC H03H 3/02; H03H 9/173; H03H 9/564; H03H 2003/021

(57) ABSTRACT

A resonator and a preparation method of a resonator, and a filter relate to the technical field of resonators. The preparation method includes: forming a piezoelectric layer, a first electrode layer, and a first bonding layer on a first substrate; patterning the first bonding layer to form a first bonding ring, a second bonding ring, and a third bonding ring, and etching an exposed part of the first electrode layer to form a first window; forming a first supporting layer and a second bonding layer on the second substrate; patterning the second bonding layer to form a fourth bonding ring and a fifth bonding ring, and etching an exposed part of the first supporting layer to form a second window and a third window to obtain a boundary ring located between the third window and the second window; bonding the third bonding ring and the fifth bonding ring, and bonding the second bonding ring and the fourth bonding ring to obtain a cavity structure of the resonator; and removing the first substrate, and forming a second electrode layer on the piezoelectric layer. According to the preparation method, preparation of the boundary ring is realized through a packaging and bonding process, and the preparation process of a resonator is simple.

### CROSS-REFERENCE TO RELATED APPLICATION

This present disclosure claims the priority to Chinese patent application No. 202210067464.9, entitled “Resonator and preparation method of a resonator, and filter”, and filed on Jan. 20, 2022 in China, and the contents of which are hereby incorporated by reference in its entirety.

### TECHNICAL FIELD

The disclosure relates to the technical field of resonators, and in particular to a resonator and a preparation method of a resonator, and a filter.

### BACKGROUND

With the rapid development of wireless communication, frequency bands become more and more crowded, and the new requirements such as integration, miniaturization, low power consumption, high performance, and low cost are put forward for filters operating in the radio frequency band. Conventional surface acoustic wave (SAW) resonators cannot achieve such technical indexes due to limitations in frequency and withstanding power. Then Film Bulk Acoustic Resonator (FBAR) has become a research hotspot in the field of radio frequency filters due to the characteristics of Complementary Metal Oxide Semiconductor (CMOS) process compatibility, high quality factor (Q value), low loss, low temperature coefficient and high power capacity.

The FBAR utilizes the inverse piezoelectric effect of a piezoelectric film by electric signal from plate electrodes on the upper and lower surfaces of piezoelectric materials. The resonator generates acoustic waves because of the inverse piezoelectric effect, and the waves propagate between the electrodes. The acoustic wave is classified into thickness-vibration modes i and transverse-vibration modes. Only the acoustic wave in the vibration mode in the thickness direction satisfying the condition of total reflection of the acoustic wave will be retained, the acoustic wave in the transverse vibration mode will be consumed, and the retained acoustic signal is converted into the electric signal for output, thereby achieving frequency selection of the electric signal. Since the acoustic wave in the transverse vibration mode causes energy loss of the acoustic wave, reduces the energy conversion efficiency, increases the insertion loss of the FBAR, and reduces the quality factor Q value, in order to improve the quality factor of a device, the quality factor is also called “Q value”, which is a performance index to evaluate the energy loss of the resonator during operation.

The larger the Q value, the lower the energy loss, and the better the performance. A method commonly used to reduce the energy loss includes setting a boundary ring, and the like. However, the boundary ring in the related art is generally obtained by process of frontal lithography. The fabrication process of a resonator is complicated, and the size accuracy of the prepared boundary ring is not high enough to meet the increasingly developing needs.

### SUMMARY

An object of the disclosure is to provide a resonator and a preparation method of a resonator, and a filter. The preparation method of the resonator realizes preparation of a boundary ring through a packaging and bonding process, and the preparation process of a resonator is simple.

Embodiments of the disclosure are implemented as follows.

In one aspect of the disclosure, a preparation method of a resonator is provided. The preparation method of the resonator may include that: a piezoelectric layer, a first electrode layer, and a first bonding layer are sequentially formed on a first substrate; the first bonding layer is patterned to form a first bonding ring, a second bonding ring surrounding a periphery of the first bonding ring, and a third bonding ring surrounding a periphery of the second bonding ring, and an exposed part of the first electrode layer is etched to form a first window between the third bonding ring and the second bonding ring; a first supporting layer and a second bonding layer are sequentially formed on a second substrate; the second bonding layer is patterned to form a fourth bonding ring and a fifth bonding ring surrounding the periphery of the fourth bonding ring, and an exposed part of the first supporting layer is etched to form a second window located between the fourth bonding ring and the fifth bonding ring and a third window located in the fourth bonding ring to obtain a boundary ring located between the third window and the second window; the third bonding ring and the fifth bonding ring are bonded, and the second bonding ring and the fourth bonding ring are bonded to obtain a cavity structure of the resonator; and the first substrate is removed, and a second electrode layer is formed on the piezoelectric layer. The preparation method of the resonator realizes preparation of the boundary ring through the packaging and bonding process, and the preparation process of a resonator is simple.

Optionally, the operation that the piezoelectric layer, the first electrode layer, and the first bonding layer are sequentially formed on the first substrate may include that: a second supporting layer is formed on the first substrate; and the piezoelectric layer, the first electrode layer, and the first bonding layer are sequentially formed on the second supporting layer.

Optionally, the operation that the first substrate is removed, and the second electrode layer is formed on the piezoelectric layer may include that: the first substrate is removed; the second supporting layer and the piezoelectric layer are etched to form a first through hole exposing the first electrode layer; the second supporting layer is etched to form a second through hole exposing the piezoelectric layer, an orthographic projection of the first through hole and an orthographic projection of the second through hole on the piezoelectric layer having no overlap; and a metallic material is deposited on the piezoelectric layer, and the metallic material is etched to form the second electrode layer and an extraction electrode which are spaced, the second electrode layer being interconnected with the piezoelectric layer through the second through hole, and the extraction electrode being interconnected with the first electrode layer through the first through hole.

Optionally, the first supporting layer and the second supporting layer are both made of silicon dioxide.

Optionally, the operation that the first bonding layer is patterned to form the first bonding ring, the second bonding ring surrounding the periphery of the first bonding ring, and the third bonding ring surrounding the periphery of the second bonding ring, and the exposed part of the first electrode layer is etched to form the first window between the third bonding ring and the second bonding ring may include that: the first bonding layer is etched to form a fifth window; the first bonding layer and the first electrode layer are etched to form the first window and the third bonding ring located at the periphery of the first window, an orthographic projection of the first window and an orthographic projection of the fifth window on the first substrate having no overlap; and the first bonding layer is etched to form a sixth window located between the fifth window and the first window to obtain the second bonding ring located in the third bonding ring and the first bonding ring located in the second bonding ring.

Optionally, the shapes of the third bonding ring and the fifth bonding ring are adapted, and the shapes of the second bonding ring and the fourth bonding ring are adapted.

Optionally, the first electrode layer and the second electrode layer are made of any one of molybdenum, aluminum, platinum, silver, tungsten, and gold respectively.

Optionally, the piezoelectric layer is made of any one of aluminum nitride, lithium niobate, lithium tantalate, and lead zirconate titanate.

Optionally, the first electrode layer, the piezoelectric layer, and the second electrode layer form a laminated structure, and an overlap area of the first electrode layer, the piezoelectric layer, the second electrode layer, and the cavity structure is constructed as an active area along a longitudinal direction of the laminated structure; and a projection of the active area on the first substrate is a first area, and projection boundaries of the first bonding ring, the second bonding ring, the third bonding ring, the fourth bonding ring, and the fifth bonding ring on the first substrate are sequentially located at the periphery of the first area.

Optionally, the first bonding ring may include a plurality of first arc segments, a first gap being arranged between two adjacent first arc segments.

Optionally, the first gap is a hole.

Optionally, the second bonding ring may include a plurality of second arc segments, a second gap being arranged between two adjacent second arc segments.

Optionally, the second gap is a hole.

Optionally, the third bonding ring may include a plurality of third arc segments, a third gap being arranged between two adjacent third arc segments.

Optionally, the fourth bonding ring may include a plurality of fourth arc segments, a fourth gap being arranged between two adjacent fourth arc segments.

Optionally, the fifth bonding ring may include a plurality of fifth arc segments, a fifth gap being arranged between two adjacent fifth arc segments.

Optionally, the first bonding ring, the second bonding ring, the third bonding ring, the fourth bonding ring, and the fifth bonding ring have the same cross-sectional shape, and the cross-sectional shape is rectangular, or trapezoidal, or arc-shaped.

Optionally, the first bonding ring, the second bonding ring, the third bonding ring, the fourth bonding ring, and the fifth bonding ring have different radial sizes of the cross-sectional shape.

In another aspect of the disclosure, a resonator is provided. The resonator is prepared by the above preparation method of the resonator.

In still another aspect of the disclosure, a filter is provided. The filter may include the above resonator.

The disclosure has the following beneficial effects.

The preparation method of the resonator provided by the disclosure includes that: a piezoelectric layer, a first electrode layer, and a first bonding layer are sequentially formed on a first substrate; the first bonding layer is patterned to form a first bonding ring, a second bonding ring surrounding a periphery of the first bonding ring, and a third bonding ring surrounding a periphery of the second bonding ring, and an exposed part of the first electrode layer is etched to form a first window between the third bonding ring and the second bonding ring; a first supporting layer and a second bonding layer are sequentially formed on a second substrate; the second bonding layer is patterned to form a fourth bonding ring and a fifth bonding ring surrounding a periphery of the fourth bonding ring, and an exposed part of the first supporting layer is etched to form a second window located between the fourth bonding ring and the fifth bonding ring and a third window located in the fourth bonding ring to obtain a boundary ring located between the third window and the second window; the third bonding ring and the fifth bonding ring are bonded, and the second bonding ring and the fourth bonding ring are bonded to obtain a cavity structure of the resonator; and the first substrate is removed, and a second electrode layer is formed on the piezoelectric layer. In the disclosure, the boundary ring structure configured to limit acoustic wave transmission is arranged at the periphery of an effective resonance area of the resonator by means of packaging and bonding, which may reduce the lateral leakage of acoustic wave energy in the resonator, thereby improving a quality factor of a device. Compared to the related art, the preparation process of the resonator provided by the disclosure is simpler, and the size accuracy of the boundary ring obtained is relatively high.

### BRIEF DESCRIPTION OF THE DRAWINGS

In order to more clearly illustrate the embodiments of the disclosure, the drawings used in the embodiments will be briefly described below. It is to be understood that the following drawings are only some embodiments of the disclosure and should not be regarded as a limitation of the scope. Other related drawings may further be obtained by those of ordinary skill in the art according to these drawings without creative efforts.

FIG. 1 is a first schematic flowchart of a preparation method of a resonator provided by the embodiments of the disclosure.

FIG. 2 is a second schematic flowchart of a preparation method of a resonator provided by the embodiments of the disclosure.

FIG. 3 is a third schematic flowchart of a preparation method of a resonator provided by the embodiments of the disclosure.

FIG. 4 is a fourth schematic flowchart of a preparation method of a resonator provided by the embodiments of the disclosure.

FIG. 5 is a first schematic diagram of a preparation process of a resonator provided by the embodiments of the disclosure.

FIG. 6 is a second schematic diagram of a preparation process of a resonator provided by the embodiments of the disclosure.

FIG. 7 is a third schematic diagram of a preparation process of a resonator provided by the embodiments of the disclosure.

FIG. 8 is a fourth schematic diagram of a preparation process of a resonator provided by the embodiments of the disclosure.

FIG. 9 is a fifth schematic diagram of a preparation process of a resonator provided by the embodiments of the disclosure.

FIG. 10 is a sixth schematic diagram of a preparation process of a resonator provided by the embodiments of the disclosure.

FIG. 11 is a seventh schematic diagram of a preparation process of a resonator provided by the embodiments of the disclosure.

FIG. 12 is an eighth schematic diagram of a preparation process of a resonator provided by the embodiments of the disclosure.

FIG. 13 is a ninth schematic diagram of a preparation process of a resonator provided by the embodiments of the disclosure.

FIG. 14 is a tenth schematic diagram of a preparation process of a resonator provided by the embodiments of the disclosure.

Reference signs: 10—first substrate; 20—piezoelectric layer; 30—first electrode layer; 31—first window; 40—first bonding layer; 41—first bonding ring; 42—second bonding ring; 43—third bonding ring; 44—fifth window; 45—sixth window; 50—second substrate; 60—first supporting layer; 61—second window; 62—third window; 63—boundary ring; 70—second bonding layer; 71—fourth bonding ring; 72—fifth bonding ring; 80—cavity structure; 90—second electrode layer; 91—second supporting layer; 92—first through hole; 93—second through hole; and 94—extraction electrode.

### DETAILED DESCRIPTION OF THE EMBODIMENTS

The implementation modes stated below represent the information necessary for those skilled in the art to practice the implementation modes, and show the best mode to practice the implementation modes. After reading the following description with reference to the drawings, those skilled in the art will understand the concepts of the disclosure, and will recognize the application of these concepts not specifically proposed herein. It is to be understood that these concepts and applications fall within the scope of the disclosure and the attached claims.

It is to be understood that, the terms first, second, etc. may be configured herein to describe various elements in the disclosure, but these elements should not be limited to these terms. These terms are only configured to distinguish one element from another. For example, without departing from the scope of the disclosure, a first element may be referred to as a second element, and similarly, the second element may also be referred to as the first element. As used herein, the term “and/or” used herein includes any and all combinations of one or more of the associated listed items.

It is to be understood that when an element (such as a layer, an area, or a substrate) is referred to as “being on another element” or “extending to another element”, it may be directly on another element or directly extend to another element, or there may be an element therebetween. On the contrary, when on element is referred to as “being directly on another element” or “directly extending to another element”, there is no element therebetween. Similarly, it is to be understood that when an element (such as a layer, an area, or a substrate) is referred to as “being on another element” or “extending on another element”, it may be directly on another element or directly extend on another element, or there may be an element therebetween. On the contrary, when an element is referred to as “being directly on another element” or “directly extending on another element”, there is no element therebetween. It is also understood that when an element is referred to as being “connected” or “coupled” to another element, it may be directly connected or coupled to another element, or there is an element therebetween. On the contrary, when an element is referred to as being “directly connected” or “directly coupled” to another element, there is no element therebetween.

Related terms such as “below” or “above” or “upper” or “lower” or “horizontal” or “vertical” may be configured herein to describe the relationship between one element, layer, or area and another element, layer, or area, as shown in the drawings. It is to be understood that these terms and those discussed above are intended to cover different orientations of an apparatus other than those depicted in the drawings.

The terms used in the disclosure are only used for the purpose of illustrating specific implementation modes, and are not intended to limit the disclosure. As used herein, singular forms “a”, “an”, and “the” are also intended to include plural forms as well, unless the context explicitly otherwise. It is also to be understood that, when used herein, the term “including” indicates the existence of the features, integers, steps, operations, elements, and/or components, but does not exclude the existence or addition of one or more other features, integers, steps, operations, elements, components, and/or groups of the foregoing.

Unless otherwise defined, all terms used herein (including technical terms and scientific terms) have the same meanings as those commonly understood by those of ordinary in the art of the disclosure. It is also to be understood that the terms used herein shall be interpreted as having the same meaning as they have in the description and related fields, and shall not be interpreted in an idealized or overly formal sense, unless they have been explicitly defined herein.

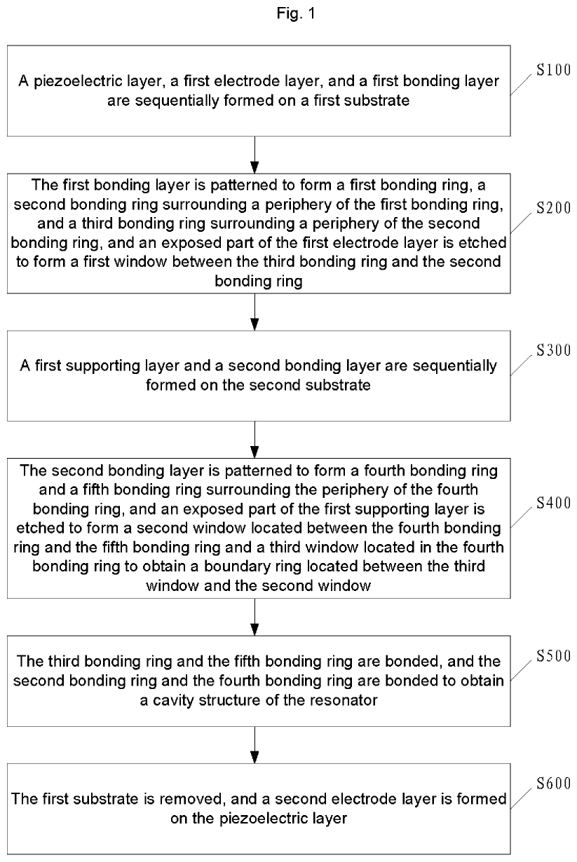

Referring to FIG. 1, the embodiments provide a preparation method of a resonator. The preparation method of the resonator includes the following operations.

At S100, a piezoelectric layer 20, a first electrode layer 30, and a first bonding layer 40 are sequentially formed on a first substrate 10.

Those skilled in the art may choose the first substrate 10 by themselves, which is not limited in the disclosure.

Optionally, the piezoelectric layer 20 may be made of any one of aluminum nitride, lithium niobate, lithium tantalate, and lead zirconate titanate.

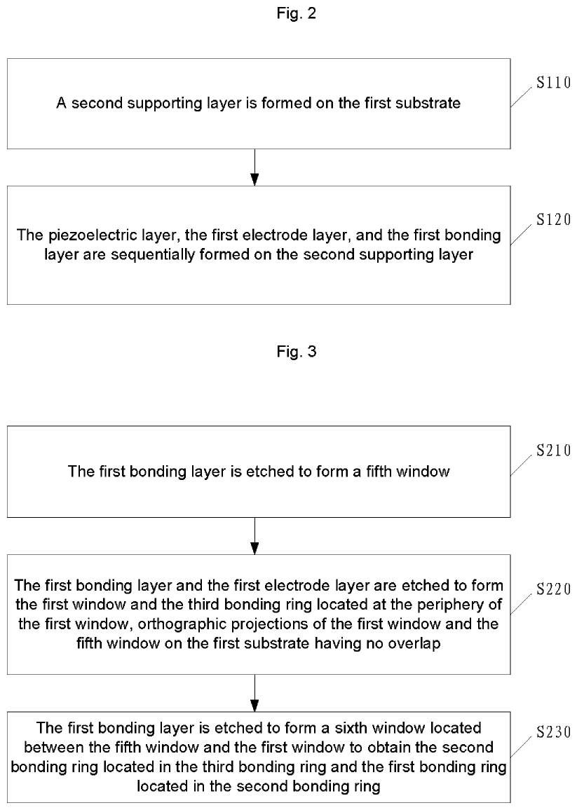

Exemplarily, referring to FIG. 2, in the S100, the piezoelectric layer 20, the first electrode layer 30, and the first bonding layer 40 are sequentially formed on the first substrate 10 specifically includes the following steps.

At S110, a second supporting layer 91 is formed on the first substrate 10.

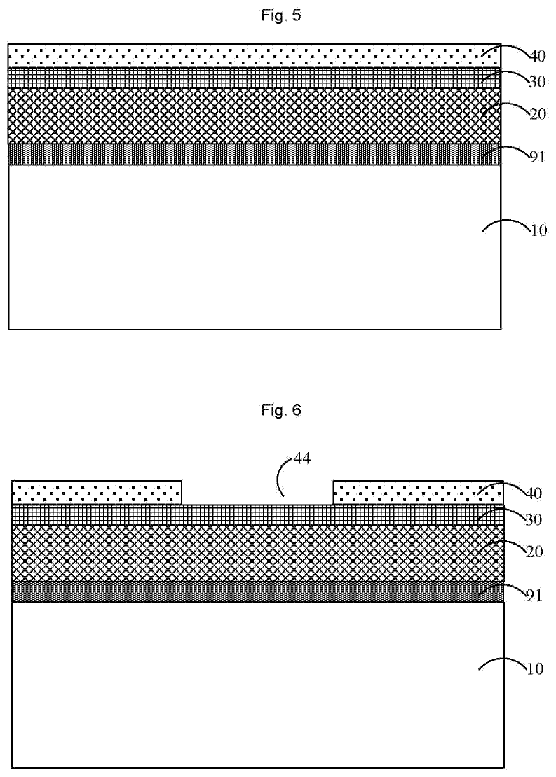

At S120, the piezoelectric layer 20, the first electrode layer 30, and the first bonding layer 40 are sequentially formed on the second supporting layer 91, as shown in FIG. 5.

Herein, the first bonding layer 40 is arranged to facilitate packaging and bonding in subsequent processes. Specifically, those skilled in the art may choose the material of the first bonding layer 40 by themselves, which is not limited in the disclosure.

At S200, the first bonding layer 40 is patterned to form a first bonding ring 41, a second bonding ring 42 surrounding the periphery of the first bonding ring 41, and a third bonding ring 43 surrounding the periphery of the second bonding ring 42, and an exposed part of the first electrode layer 30 is etched to form a first window 31 between the third bonding ring 43 and the second bonding ring 42, as shown in FIG. 8.

It is to be noted that the outer diameter of the first bonding ring 41 is smaller than the inner diameter of the second bonding ring 42, and the outer diameter of the second bonding ring 42 is smaller than the inner diameter of the third bonding ring 43. Thus, the first bonding ring 41, the second bonding ring 42, and the third bonding ring 43 may be annularly sleeved as shown in FIG. 8.

Also, in the embodiment, gaps are formed between the first bonding ring 41 and the second bonding ring 42, and between the second bonding ring 42 and the third bonding ring 43 due to patterning.

Exemplarily, as shown in FIG. 3, the S200 that the first bonding layer 40 is patterned to form the first bonding ring 41, the second bonding ring 42 surrounding the periphery of the first bonding ring 41, and the third bonding ring 43 surrounding the periphery of the second bonding ring 42, and an exposed part of the first electrode layer 30 is etched to form the first window 31 between the third bonding ring 43 and the second bonding ring 42 specifically includes the following steps.

At S210, the first bonding layer 40 is etched to form a fifth window 44, as shown in FIG. 6.

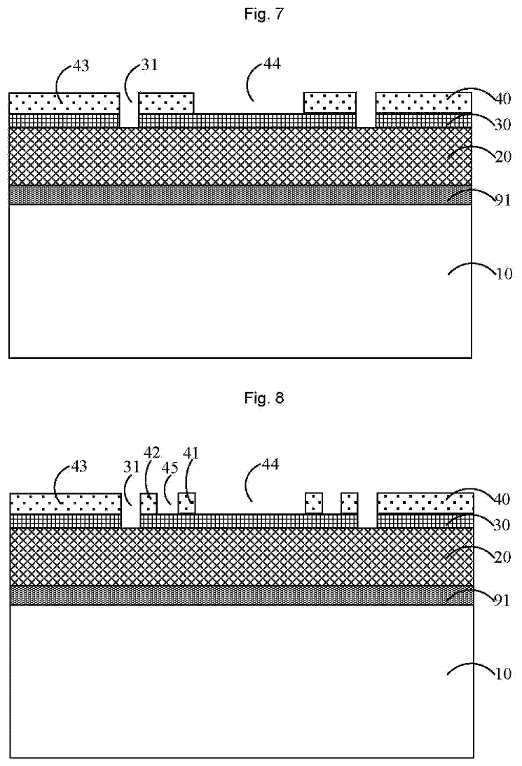

At S220, the first bonding layer 40 and the first electrode layer 30 are etched to form the first window 31 and the third bonding ring 43 located at the periphery of the first window 31, orthographic projections of the first window 31 and the fifth window 44 on the first substrate 10 having no overlap, as shown in FIG. 7.

Specifically, those skilled in the art may determine the size of the first window 31 and the size of the fifth window 44 according to actual requirements.

At S230, the first bonding layer 40 is etched to form a sixth window 45 located between the fifth window 44 and the first window 31 to obtain the second bonding ring 42 located in the third bonding ring 43 and the first bonding ring 41 located in the second bonding ring 42, as shown in FIG. 8.

Herein, in the embodiment, the sixth window 45 is arranged on the first bonding layer 40, and the orthographic projection of a resonator on the first substrate 10, the orthographic projection of the fifth window 44 on the first substrate 10, and the orthographic projection of the first window 31 on the first substrate 10 have no overlap.

In the disclosure, by etching the first bonding layer 40 to form the fifth window 44, etching the first bonding layer 40 and the first electrode layer 30 to form the first window 31, and etching the first bonding layer 40 to form the sixth window 45, the first bonding ring 41, the second bonding ring 42 and the third bonding ring 43 may be formed on the first bonding layer 40, as shown in FIG. 8.

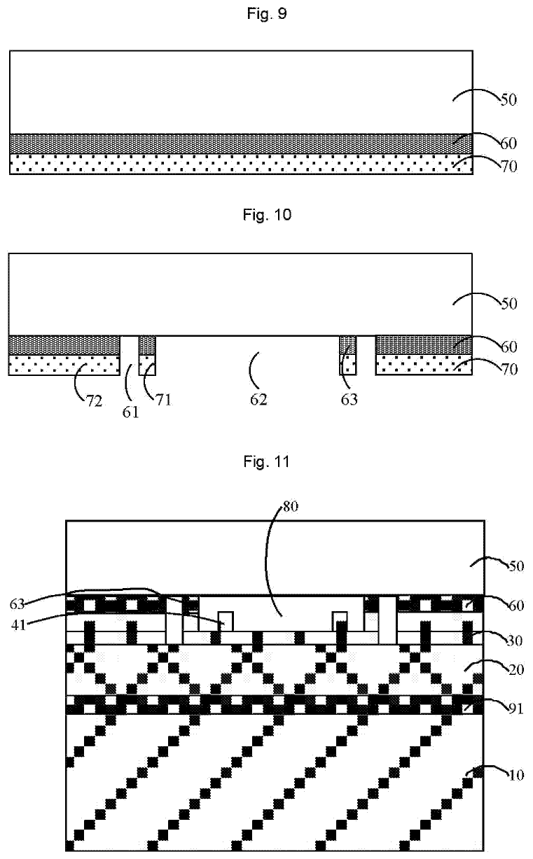

At S300, a first supporting layer 60 and a second bonding layer 70 are sequentially formed on the second substrate 50, as shown in FIG. 9.

The materials of the first supporting layer 60 and the second supporting layer 91 may be the same. Exemplarily, the first supporting layer 60 and the second supporting layer 91 are both made of silicon dioxide.

At S400, the second bonding layer 70 is patterned to form a fourth bonding ring 71 and a fifth bonding ring 72 surrounding the periphery of the fourth bonding ring 71, and an exposed part of the first supporting layer 60 is etched to form a second window 61 located between the fourth bonding ring 71 and the fifth bonding ring 72 and a third window 63 located in the fourth bonding ring 71 to obtain a boundary ring 63 located between the third window 62 and the second window 61, as shown in FIG. 10.

It is to be noted that the fourth bonding ring 71 and the fifth bonding ring 72 are formed by etching the second bonding layer 70 to form two etching windows in the disclosure. One of the etching windows is located in the fourth bonding ring 71, and the other etching window is annular and located at the periphery of the fourth bonding ring 71.

After the fourth bonding ring 71 and the fifth bonding ring 72 are formed, an exposed part of the first supporting layer 60 is etched to obtain the structure shown in FIG. 10. At this time, the boundary ring 63 is formed.

At S500, the third bonding ring 43 and the fifth bonding ring 72 are bonded, and the second bonding ring 42 and the fourth bonding ring 71 are bonded to obtain a cavity structure 80 of the resonator, as shown in FIG. 11.

In the embodiment, the shapes of the third bonding ring 43 and the fifth bonding ring 72 are adapted, and the shapes of the second bonding ring 42 and the fourth bonding ring 71 are adapted. In this way, bonding of the first bonding layer 40 and the second bonding layer 70 may be facilitated.

At S600, the first substrate 10 is removed, and a second electrode layer 90 is formed on the piezoelectric layer 20, as shown in FIG. 14.

Optionally, the first electrode layer 30 and the second electrode layer 90 are made of any one of molybdenum, aluminum, platinum, silver, tungsten, and gold respectively.

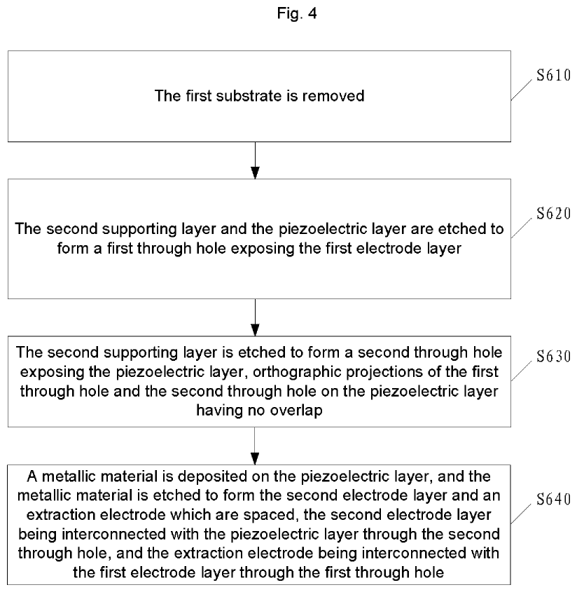

Referring to FIG. 4, in the embodiment, the S600 that the first substrate 10 is removed, and the second electrode layer 90 is formed on the piezoelectric layer 20 specifically includes the following steps.

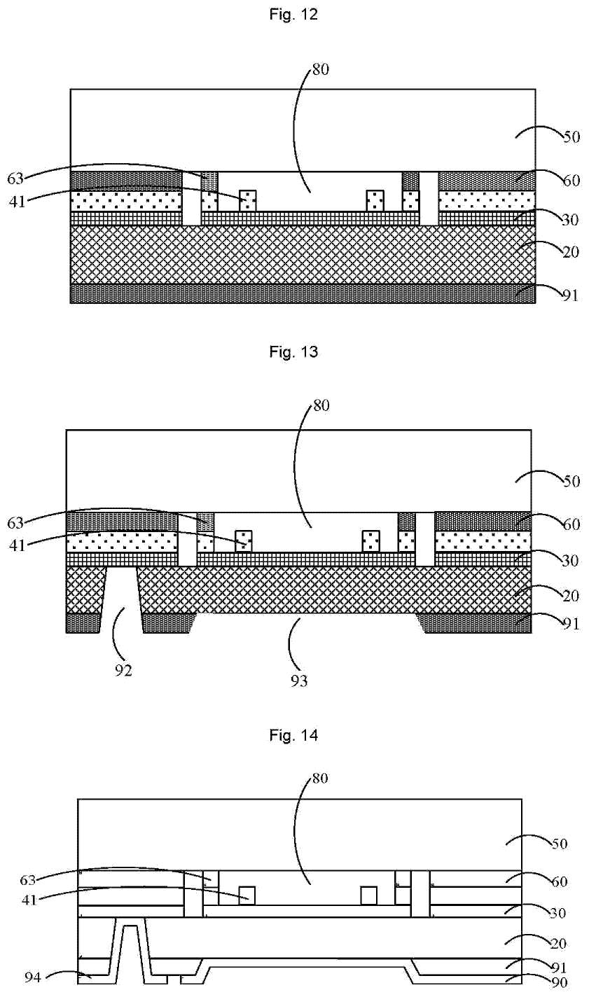

At S610, the first substrate 10 is removed, as shown in FIG. 12.

At S620, the second supporting layer 91 and the piezoelectric layer 20 are etched to form a first through hole 92 exposing the first electrode layer 30, as shown in FIG. 13.

The first through hole 92 is arranged to facilitate the extraction of the first electrode layer 30 to the side, close to the second electrode layer 90, of the second supporting layer 91. Specifically, those skilled in the art may determine the size of the first through hole 92 according to actual situations, which is not limited in the disclosure.

At S630, the second supporting layer 91 is etched to form a second through hole 93 exposing the piezoelectric layer 20, orthographic projections of the first through hole 92 and the second through hole 93 on the piezoelectric layer 20 having no overlap, as shown in FIG. 13.

The second through hole 93 is arranged to facilitate the formation of the second electrode layer 90 on an exposed part of the piezoelectric layer 20.

At S640, a metallic material is deposited on the piezoelectric layer 20, and the metallic material is etched to form the second electrode layer 90 and an extraction electrode 94 which are spaced, the second electrode layer 90 being interconnected with the piezoelectric layer 20 through the second through hole 93, and the extraction electrode 94 being interconnected with the first electrode layer 30 through the first through hole 92, as shown in FIG. 14.

The first electrode layer 30, the piezoelectric layer 20, and the second electrode layer 90 form a laminated structure, and an overlap area of the first electrode layer 30, the piezoelectric layer 20, the second electrode layer 90, and the cavity structure is constructed as an active area in a longitudinal direction of the laminated structure. A projection of the active area on the first substrate 10 is a first area, and projection boundaries of the first bonding ring 41, the second bonding ring 42, the third bonding ring 43, the fourth bonding ring 71, and the fifth bonding ring 72 on the first substrate 10 are sequentially located at the periphery of the first area.

The first bonding ring 41 includes a plurality of first arc segments, a first gap being arranged between two adjacent first arc segments.

The first gap is a hole.

The second bonding ring 42 includes a plurality of second arc segments, a second gap being arranged between two adjacent second arc segments.

The second gap is a hole.

The third bonding ring 43 includes a plurality of third arc segments, a third gap being arranged between two adjacent third arc segments.

The fourth bonding ring 71 includes a plurality of fourth arc segments, a fourth gap being arranged between two adjacent fourth arc segments.

The fifth bonding ring 72 includes a plurality of fifth arc segments, a fifth gap being arranged between two adjacent fifth arc segments.

The first bonding ring 41, the second bonding ring 42, the third bonding ring 43, the fourth bonding ring 71, and the fifth bonding ring 72 have the same cross-sectional shape, and the cross-sectional shape is rectangular, trapezoidal, or arc-shaped.

The first bonding ring 41, the second bonding ring 42, the third bonding ring 43, the fourth bonding ring 71, and the fifth bonding ring 72 have different radial sizes of the cross-sectional shape.

The first bonding ring 41, the second bonding ring 42, the third bonding ring 43, the fourth bonding ring 71, and the fifth bonding ring 72 may be segmented. From the perspective of a top view, the first bonding ring 41, the second bonding ring 42, the third bonding ring 43, the fourth bonding ring 71, the fifth bonding ring 72, the first window 31, the fifth window 44, the sixth window 45, the second window 61, and the third window 62 surrounds the periphery of the active area of the resonator, and the first bonding ring 41, the second bonding ring 42, the third bonding ring 43, the fourth bonding ring 71, and the fifth bonding ring 72 may be of a segmented design, such as being divided into two segments, three segments, four segments, etc. and the beneficial effects of the segmented design are that the stress may be balanced and excessive stress may be prevented during bonding.

In terms of width, the width of the distance (window) between the bonding ring and the adjacent bonding ring should be greater than or equal to 1110 times the wavelength of the excited acoustic wave and smaller than or equal to 10 times the wavelength, which comprehensively considers the preparation feasibility and device performance improvement.

The first bonding ring 41, the second bonding ring 42, the third bonding ring 43, the fourth bonding ring 71, the fifth bonding ring 72, the first window 31, the fifth window 44, the sixth window 45, the second window 61, and the third window 62 surround the periphery of the active area of the device, the whole widths of the first bonding ring 41, second bonding ring 42, third bonding ring 43, fourth bonding ring 71, and fifth bonding ring 72 are uniform, and the ring width may be also designed to be varied.

From the perspective of materials, the bonding rings are made of a high acoustic impedance material, and the window between the bonding rings should be made of no material or a low acoustic impedance material. One of the preferred structures also uses materials with different acoustic impedances for different bonding rings to form a stronger energy limitation effect.

The structure of the bonding ring may not be a complete ring, and the preferred structure may design some holes in the middle of the ring, that is, the bonding ring may be a ring with a plurality of hole-shaped notches in the middle, and the function of the holes is, on the one hand, to form a new window in the boundary ring, and the alternating high and low acoustic impedances may enhance the energy limitation effect. On the other hand, since there is stress causing strain when bonding, the existence of holes may balance the stress.

From the perspective of a top view, the bonding rings/windows should surround the periphery of the active area of the device, a segmented design of the bonding rings/windows may be supplemented in the claims and description, such as into two segments, three segments, four segments, etc. and the functions and beneficial effects of the segmentation are that the stress may be balanced and excessive stress may be prevented during the whole ring bonding.

In terms of width, the width of the distance (window) between the bonding ring and the adjacent bonding ring should be greater than or equal to 1/10 times the wavelength of the excited acoustic wave and smaller than or equal to 10 times the wavelength. This limitation comprehensively considers the preparation feasibility and device performance improvement.

From the top view, the bonding rings/windows surround the active area of the device, in Embodiment 1, the whole ring widths are uniform and are the same everywhere, and in Embodiment 2, the whole ring width may be varied.

From the perspective of materials, the bonding rings are made of a high acoustic impedance material, and the window between the bonding rings should be made of no material or a low acoustic impedance material. One of the preferred structures also uses materials with different acoustic impedances for different bonding rings to form a stronger energy limitation effect.

The structure of the bonding ring may not be a complete ring, and the preferred structure may design some holes in the middle of the ring, that is, the bonding ring may be a ring with a plurality of hole-shaped notches in the middle, and the function of the holes is, on the one hand, to form a new window in the boundary ring, and the alternating high and low acoustic impedances may enhance the energy limitation effect. On the other hand, since there is stress causing strain when bonding, the existence of holes may balance the stress.

In summary, the preparation method of the resonator provided by the disclosure includes that: a piezoelectric layer 20, a first electrode layer 30, and a first bonding layer 40 are sequentially formed on a first substrate 10; the first bonding layer 40 is patterned to form a first bonding ring 41, a second bonding ring 42 surrounding the periphery of the first bonding ring 41, and a third bonding ring 43 surrounding the periphery of the second bonding ring 42, and an exposed part of the first electrode layer 30 is etched to form a first window 31 between the third bonding ring 43 and the second bonding ring 42; a first supporting layer 60 and a second bonding layer 70 are sequentially formed on the second substrate 50; the second bonding layer 70 is patterned to form a fourth bonding ring 71 and a fifth bonding ring 72 surrounding the periphery of the fourth bonding ring 71, and an exposed part of the first supporting layer 60 is etched to form a second window 61 located between the fourth bonding ring 71 and the fifth bonding ring 72 and a third window 62 located in the fourth bonding ring 71 to obtain a boundary ring 63 located between the third window 62 and the second window 61; the third bonding ring 43 and the fifth bonding ring 72 are bonded, and the second bonding ring 42 and the fourth bonding ring 71 are bonded to obtain a cavity structure 80 of the resonator; and the first substrate 10 is removed, and a second electrode layer 90 is formed on the piezoelectric layer 20. In the disclosure, the boundary ring 63 structure configured to limit acoustic wave transmission is arranged at the periphery of an effective resonance area of the resonator by means of packaging and bonding, which may reduce the lateral leakage of acoustic wave energy in the resonator, thereby improving a quality factor of a device. Compared to the related art, the preparation process of the resonator provided by the disclosure is simpler, and the size accuracy of the boundary ring 63 obtained is relatively high.

In another aspect of the disclosure, a resonator is provided. The resonator is prepared by the above preparation method of the resonator. The specific steps of the preparation method of the resonator and the beneficial effects of a resonator have been described in detail above, which will not be repeated in the disclosure.

In still another aspect of the disclosure, a filter is provided. The filter may include the above resonator. The specific structure of the above resonator may be learned from the preparation method described above, which will not be repeated in the disclosure.

The above are only the optional embodiments of the disclosure, and are not intended to limit the disclosure. For those of ordinary skill in the art, various modifications and changes may be made to the disclosure. Any modifications, equivalent substitutions, improvements, etc. within the spirit and scope of the disclosure shall be included in the scope of protection of the disclosure.

1. A preparation method of a resonator, comprising:
sequentially forming a piezoelectric layer, a first electrode layer, and a first bonding layer on a first substrate;
patterning the first bonding layer to form a first bonding ring, a second bonding ring surrounding a periphery of the first bonding ring, and a third bonding ring surrounding a periphery of the second bonding ring; and etching an exposed part of the first electrode layer to form a first window between the third bonding ring and the second bonding ring;
sequentially forming a first supporting layer and a second bonding layer on a second substrate;
patterning the second bonding layer to form a fourth bonding ring and a fifth bonding ring surrounding a periphery of the fourth bonding ring; and etching an exposed part of the first supporting layer to form a second window located between the fourth bonding ring and the fifth bonding ring and a third window located in the fourth bonding ring to obtain a boundary ring located between the third window and the second window;
bonding the third bonding ring and the fifth bonding ring, and bonding the second bonding ring and the fourth bonding ring to obtain a cavity structure of the resonator; and
removing the first substrate, and forming a second electrode layer on the piezoelectric layer.

2. The preparation method of the resonator of claim 1, wherein, sequentially forming the piezoelectric layer, the first electrode layer, and the first bonding layer on the first substrate comprises:
forming a second supporting layer on the first substrate; and
sequentially forming the piezoelectric layer, the first electrode layer, and the first bonding layer on the second supporting layer.

3. The preparation method of the resonator of claim 2, wherein, removing the first substrate, and forming the second electrode layer on the piezoelectric layer comprises:
removing the first substrate;
etching the second supporting layer and the piezoelectric layer to form a first through hole exposing the first electrode layer;
etching the second supporting layer to form a second through hole exposing the piezoelectric layer, wherein an orthographic projection of the first through hole and an orthographic projection of the second through hole on the piezoelectric layer have no overlap; and
depositing a metallic material on the piezoelectric layer, and etching the metallic material to form the second electrode layer and an extraction electrode which are spaced, the second electrode layer being interconnected with the piezoelectric layer through the second through hole, and the extraction electrode being interconnected with the first electrode layer through the first through hole.

4. The preparation method of the resonator of claim 2, wherein the first supporting layer and the second supporting layer are both made of silicon dioxide.

5. The preparation method of the resonator of claim 1, wherein, patterning the first bonding layer to form the first bonding ring, the second bonding ring surrounding the periphery of the first bonding ring, and the third bonding ring surrounding the periphery of the second bonding ring, and etching the exposed part of the part of the first electrode layer to form the first window between the third bonding ring and the second bonding ring comprises:
etching the first bonding layer to form a fifth window;
etching the first bonding layer and the first electrode layer to form the first window and the third bonding ring located at the periphery of the first window, wherein an orthographic projection of the first window and an orthographic projection of the fifth window on the first substrate have no overlap; and
etching the first bonding layer to form a sixth window located between the fifth window and the first window to obtain the second bonding ring located in the third bonding ring and the first bonding ring located in the second bonding ring.

6. The preparation method of the resonator of claim 1, wherein the shapes of the third bonding ring and the fifth bonding ring are adapted, and the shapes of the second bonding ring and the fourth bonding ring are adapted.

7. The preparation method of the resonator of claim 1, wherein the first electrode layer and the second electrode layer are made of any one of molybdenum, aluminum, platinum, silver, tungsten, and gold respectively.

8. The preparation method of the resonator of claim 1, wherein the piezoelectric layer is made of any one of aluminum nitride, lithium niobate, lithium tantalate, and lead zirconate titanate.

9. The preparation method of the resonator of claim 1, wherein the first electrode layer, the piezoelectric layer, and the second electrode layer form a laminated structure, and an overlap area of the first electrode layer, the piezoelectric layer, the second electrode layer, and the cavity structure is constructed as an active area along a longitudinal direction of the laminated structure; and a projection of the active area on the first substrate is a first area, and projection boundaries of the first bonding ring, the second bonding ring, the third bonding ring, the fourth bonding ring, and the fifth bonding ring on the first substrate are sequentially located at a periphery of the first area.

10. The preparation method of the resonator of claim 9, wherein the first bonding ring comprises a plurality of first arc segments, a first gap being arranged between two adjacent first arc segments.

11. The preparation method of the resonator of claim 10, wherein the first gap is a hole.

12. The preparation method of the resonator of claim 9, wherein the second bonding ring comprises a plurality of second arc segments, a second gap being arranged between two adjacent second arc segments.

13. The preparation method of the resonator of claim 12, wherein the second gap is a hole.

14. The preparation method of the resonator of claim 9, wherein the third bonding ring comprises a plurality of third arc segments, a third gap being arranged between two adjacent third arc segments.

15. The preparation method of the resonator of claim 9, wherein the fourth bonding ring comprises a plurality of fourth arc segments, a fourth gap being arranged between two adjacent fourth arc segments.

16. The preparation method of the resonator of claim 9, wherein the fifth bonding ring comprises a plurality of fifth arc segments, a fifth gap being arranged between two adjacent fifth arc segments.

17. The preparation method of the resonator of claim 9, wherein the first bonding ring, the second bonding ring, the third bonding ring, the fourth bonding ring, and the fifth bonding ring have same cross-sectional shape, and the cross-sectional shape is rectangular, or trapezoidal, or arc-shaped.

18. The preparation method of the resonator of claim 17, wherein the first bonding ring, the second bonding ring, the third bonding ring, the fourth bonding ring, and the fifth bonding ring have different radial sizes of the cross-sectional shape.

19. A resonator, prepared by the preparation method of the resonator of claim 1.

20. A filter, comprising the resonator of claim 9.
